(19) United States
(12) Patent Application Publication
(10) Pub. No.: US 2025/0282280 A1
(43) Pub. Date: Sep. 11, 2025

(54) LIGHT EMITTING DEVICE AND VEHICLE INCLUDING THE SAME

(71) Applicant: HYUNDAI MOBIS CO., LTD., Seol (KR)

(72) Inventors: Bo Ram YOON, Yongin-si (KR); Sang Pil GOO, Yongin-si (KR)

(73) Assignee: HYUNDAI MOBIS CO., LTD., Seoul (KR)

(21) Appl. No.: 18/600,266

(22) Filed: Mar. 8, 2024

(30) Foreign Application Priority Data
Sep. 14, 2023 (KR) 10-2023-0122583

(51) Int. Cl. B60Q 1/26; B60Q 1/32; B60Q 1/50; F16D 65/00; F21S 4/22; F21Y 103/10; F21Y 113/00; F21Y 115/10; H01L 25/075; H05B 45/30

(52) U.S. Cl. CPC B60Q 1/2661; B60Q 1/326; B60Q 1/543; F16D 65/005; F21S 4/22; H05B 45/30; B60Q 2400/20; F21Y 2103/10; F21Y 2113/00; F21Y 2115/10; H01L 25/0753

(57) ABSTRACT

A light emitting device provided in a vehicle includes a caliper body, an installation bracket located on an accommodation surface inside the caliper body, a light emitting module installed on the installation bracket and configured to emit light into a gap of the caliper body, a cable connected to the light emitting module, and an electronic control unit (ECU) connected to the cable, wherein the ECU controls at least one of a color, brightness, or cycle of the light emitted from the light emitting module. The light emitting device includes a light emitting module that emits light into a gap of a caliper body, and controls the light emitting module through an electronic control unit to beautify the caliper body.

This application claims the benefit of Korean Patent Application No. 10-2023-0122583, filed on Sep. 14, 2023, which is hereby incorporated by reference as if fully set forth herein.

### BACKGROUND OF THE DISCLOSURE

### Field of the Disclosure

The present disclosure relates to a light emitting device and a vehicle including the same, for emitting light into a gap of a caliper body into which a brake disc of the vehicle is inserted.

### Discussion of the Related Art

A brake device mounted in a vehicle is a device for decelerating, stopping, or maintaining a stopped state of a vehicle while driving and is located inside a rotating wheel, and brakes a vehicle by strongly pressing a disc-shaped brake disc rotating together with the wheel using brake pads from both sides.

In a typical brake device, a pair of brake pads disposed on both sides of a brake disc are supported in a state in which the brake pads are capable of advancing and retreating on an accommodation surface in a caliper body fixed to a vehicle. A pad support pin to guide the advance and retreat of the brake pads, and a spring member to elastically support upper parts of the two pad plates to prevent the pad plates from shaking and to ensure smooth return are installed.

With development of vehicle technology, a demand for beautification of the caliper body exposed out of the vehicle has increased. For example, various colors or lettering is applied to the caliper body.

When a light emitting device is applied to the caliper body, the demand for beautification of the caliper body is satisfied. For example, when driving at night, the light emitting device allows surrounding pedestrians or drivers of surrounding vehicles to recognize presence of the vehicle, thereby improving the safety as well as the decoration of the vehicle. Therefore, a need to apply the light emitting device to the caliper body is very high.

Brake devices that pressurize the brake pads in a direction of the brake disc are largely divided into a hydraulic brake and an electromechanical brake (EMB).

A hydraulic braking method is a method of generating braking force by advancing and retracting a brake pad through pressure generated by brake fluid in a cylinder when a driver applies a brake using a traditional braking method.

However, in the case of a hydraulic brake method, to apply a light emitting device to a caliper body, separate power supply devices connected to the light emitting device are required. In the end, there is a problem that it is difficult to apply the hydraulic brake method because the number of additional components required inevitably increases and an installation structure is also complicated.

In contrast, unlike an existing hydraulic brake system, in an EMB, a force with which a driver presses a brake pedal is converted into an electrical signal and the electrical signal is transmitted to an electronic control unit (ECU), and the ECU is a system that calculates a vehicle state and braking force and operates a motor to generate a braking force of an electric caliper.

In the case of the EMB, the EMB includes an electronic controller as described above, and thus it is easy to apply a light emitting device to a caliper body and supply and control power required to emit light through the electronic controller.

### SUMMARY OF THE DISCLOSURE

The present disclosure provides a light emitting device and a vehicle including the same, and more particularly, to a light emitting device and a vehicle including the same that includes a light emitting module that emits light into a gap of a caliper body, and control the light emitting module through an electronic control unit to beautify the caliper body.

The present disclosure provides a light emitting device and a vehicle including the same, for providing visual notification by checking the wear state of the brake pad through the wear sensor and controlling the light emitting module.

The present disclosure provides a light emitting device and a vehicle including the same, for providing visual information by controlling the light emitting module based on the driving information of the vehicle.

It will be appreciated by persons skilled in the art that the objects that could be achieved with the present disclosure are not limited to what has been particularly described hereinabove and the above and other objects that the present disclosure could achieve will be more clearly understood from the following detailed description.

A light emitting device provided in a vehicle includes a caliper body, an installation bracket located on an accommodation surface inside the caliper body, a light emitting module installed on the installation bracket and configured to emit light into a gap of the caliper body, a cable connected to the light emitting module, and an electronic control unit (ECU) connected to the cable, wherein the ECU controls at least one of a color, brightness, or cycle of the light emitted from the light emitting module.

The light emitting module may include a plurality of light emitting diodes (LEDs), and an LED array member on which the plurality of LEDs are arranged, wherein the LED array member includes a bendable strap or line form.

The light emitting device may further include a brake pad apart from the installation bracket and located inside the caliper body, and the light emitting module may include a wear sensor that is coupled to the LED array member and is in contact with one surface of the brake pad.

The ECU may control the light emitting module based on a change in resistance value measured by the wear sensor.

The light emitting module may include a cover member configured to cover the plurality of LEDs and surround the LED array member.

The LED array member may be attached to the installation bracket through an adhesive or fastened and coupled to the installation bracket through a bolt.

The light emitting device may further include a cable holder coupled to the caliper body and configured to support the cable, and the cable holder may include a hook in contact with the cable.

The ECU may control the light emitting module based on driving information of the vehicle.

The driving information may include at least one of information on a driving mode, a driving direction, parking, or an external environment.

A vehicle includes a vehicle body, a plurality of wheels located at a lower part of the vehicle body to rotate and including a brake disc, and a plurality of light emitting devices provide in the plurality of wheels, respectively, wherein at least one of the plurality of light emitting devices includes a caliber body into which one end of the brake disc is inserted, an installation bracket located on an accommodation surface inside the caliper body, a light emitting module installed on the installation bracket and configured to emit light into a gap of the caliper body, a cable connected to the light emitting module, and an electronic control unit (ECU) connected to the cable, wherein the ECU controls at least one of a color, brightness, or cycle of the light emitted from the light emitting module.

### BRIEF DESCRIPTION OF THE DRAWINGS

FIG. 1 is a diagram of a light emitting device viewed from the front, according to an embodiment of the present disclosure.

FIG. 2 is a diagram illustrating a shape in which light is emitted into a gap of a caliper body in a light emitting device according to an embodiment of the present disclosure.

FIG. 3 is a diagram of a light emitting device viewed from the side, according to an embodiment of the present disclosure.

FIG. 4 is a diagram illustrating an installation bracket located on a caliper body in a light emitting device according to an embodiment of the present disclosure.

FIG. 5 is an exploded diagram of a light emitting device according to an embodiment of the present disclosure.

FIG. 6 is a diagram showing a light emitting device according to an embodiment of the present disclosure.

FIG. 7 is a diagram for explaining a wear sensor of a light emitting device according to an embodiment of the present disclosure.

### DETAILED DESCRIPTION OF THE DISCLOSURE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

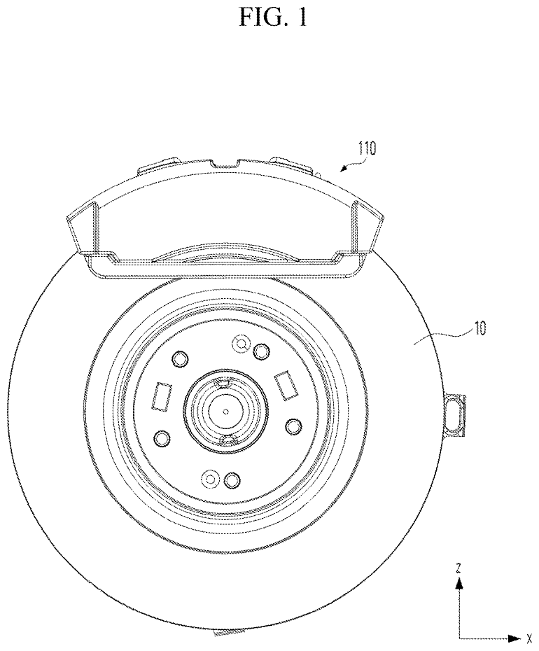

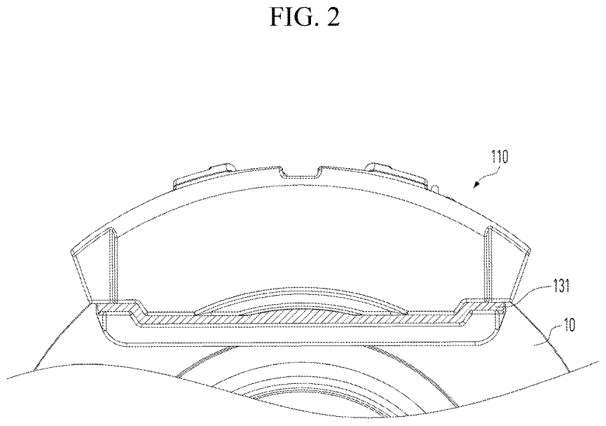

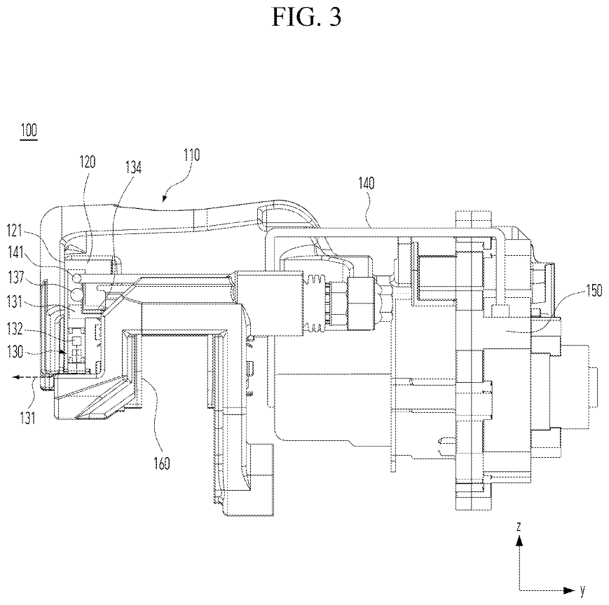

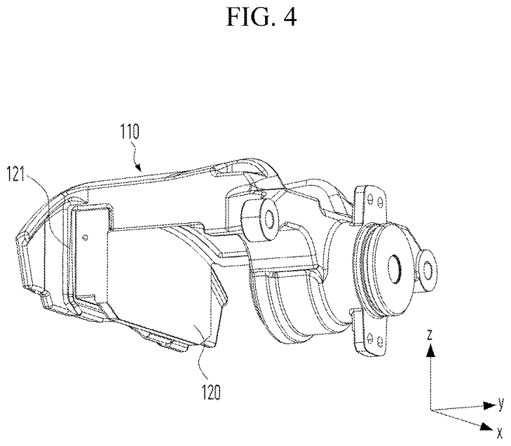

FIG. 1 is a diagram of a light emitting device 100 viewed from the front, according to an embodiment of the present disclosure. FIG. 2 is a diagram illustrating a shape in which light 131 is emitted into a gap of a caliper body 110 in the light emitting device 100 according to an embodiment of the present disclosure. FIG. 3 is a diagram of the light emitting device 100 viewed from the side, according to an embodiment of the present disclosure. FIG. 4 is a diagram illustrating an installation bracket 120 located on the caliper body 110 in the light emitting device 100 according to an embodiment of the present disclosure.

Hereinafter, in describing the light emitting device 100 according to an embodiment of the present disclosure, left and right directions are based on the x-axis direction, forward and rearward directions are based on the y-axis direction, and up and down directions are based on the z-axis direction.

The wheels of a vehicle are generally arranged on both left and right sides, and a front direction shown in FIG. 1 may be directed toward the outside of the vehicle. The vehicle may be braked by pressing a brake disc 10 of the vehicle using a brake pad 160 shown in FIG. 3. While the vehicle travels, the brake disc 10 may rotate with the wheel, and when pressure is applied to the brake disc 10 through the brake pad 160, the applied resistance acts as resistance to rotation of the brake disc 10 to reduce a rotational speed of the wheel.

Referring to FIGS. 2 and 3, the light emitting device 100 according to an embodiment of the present disclosure may include the caliper body 110, the installation bracket 120, a light emitting module 130, a cable 140, and an electronic controller 150. In some implementations, the electronic controller 150 is referred to as an electronical control unit (ECU), According to an exemplary embodiment of the present disclosure, the electronic controller 150 may include a processor (e.g., computer, microprocessor, CPU, ASIC, circuitry, logic circuits, etc.) and an associated non-transitory memory storing software instructions which, when executed by the processor, provides the functionalities of the electronic controller 150. Herein, the memory and the processor may be implemented as separate semiconductor circuits. Alternatively, the memory and the processor may be implemented as a single integrated semiconductor circuit. The processor may embody one or more processor(s).

The installation bracket 120 may be located on an accommodation surface 121 inside the caliper body 110. Referring to FIG. 4 together, in the caliper body 110, the accommodation surface 121 may be formed by processing a side surface portion and a lower end portion inside the caliper body 110 to accommodate the installation bracket 120 thereon.

The light emitting module 130 may be installed on the installation bracket 120, and as shown in FIGS. 2 and 3, the light 131 may be emitted into a gap of the caliper body 110 through the light emitting module 130.

In more detail, the light emitting module 130 may include a plurality of light emitting diodes (LEDs) 132, and the plurality of LEDs 132 may be apart from each other and disposed in an LED array member 133. Here, the LED array member 133 may include a bendable strap or line form.

According to an embodiment, as shown in FIG. 3, the LED array member 133 may be attached or coupled along an outer surface of the installation bracket 120 in the form of a strap and installed on the installation bracket 120. More specifically, the LED array member 133 may be attached to the installation bracket 120 through an adhesive or fastened and coupled to the installation bracket 120 through a bolt 137 to be fixed to the installation bracket 120.

In the light emitting device 100 according to an embodiment of the present disclosure, the cable 140 may be connected to the light emitting module 130 and the electronic controller 150 configured to control the light emitting module 130.

As such, as described above, the light emitting module 130 and the electronic controller 150 may be connected to each other through the cable 140 by applying an electromechanical brake (EMB) including the electronic controller 150 without a separate power supply device for supplying power to the light emitting module 130, and power may be supplied to the light emitting module 130 through the electronic controller 150 and the light emitting module 130 may be controlled.

The light emitting device 100 according to an embodiment of the present disclosure may further include the brake pad 160 apart from the installation bracket 120 and located inside the caliper body 110, and the light emitting module 130 may include a wear sensor 134 that is coupled to the LED array member 133 and is in contact with one surface of the brake pad 160, which will be described below in more detail.

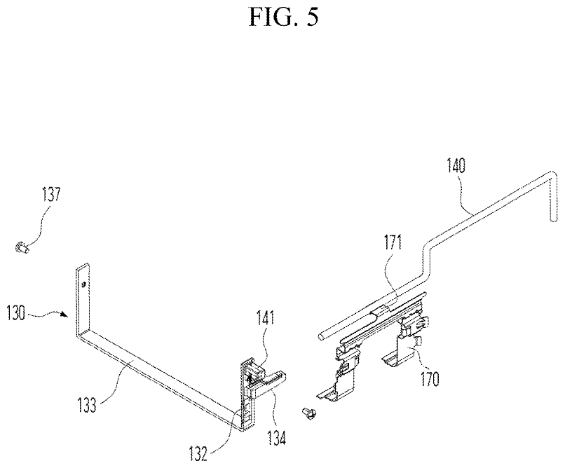

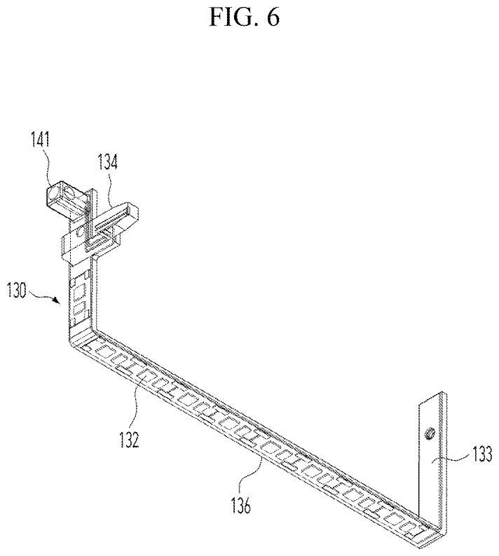

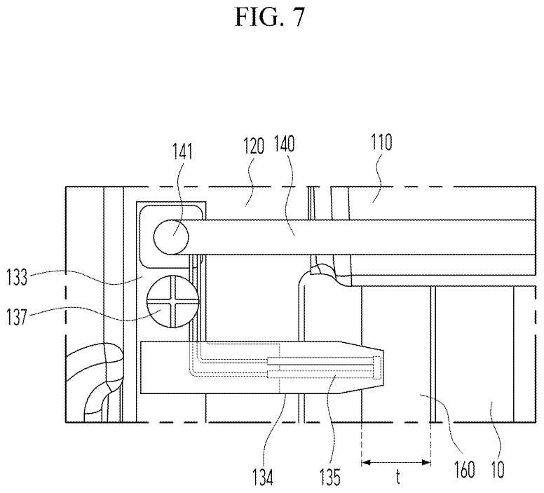

FIG. 5 is an exploded diagram of the light emitting device 100 according to an embodiment of the present disclosure. FIG. 6 is a diagram showing the light emitting device 100 according to an embodiment of the present disclosure. FIG. 7 is a diagram for explaining the wear sensor 134 of the light emitting device 100 according to an embodiment of the present disclosure.

The light emitting device 100 according to an embodiment of the present disclosure may include the light emitting module 130 and the cable 140 connected to the light emitting module 130 and may further include a cable holder 170 as shown in FIG. 5.

The cable holder 170 may be coupled to the caliper body 110 and may support the cable 140 to prevent the cable 140 from interfering with other devices or members. The cable holder 170 may include a hook 171 that comes into contact with the cable 140 and supports the cable 140.

Referring to FIGS. 5 and 6 together, in the light emitting device 100 according to an embodiment of the present disclosure, the light emitting module 130 may include the plurality of LEDs 132 and the LED array member 133 on which the plurality of LEDs 132 are arranged, as described above. The LED array member 133 may include a bendable strap or line form, as described above.

The light emitting module 130 may include a cover member 136 that covers the plurality of LEDs 132 and surrounds the LED array member 133. The cover member 136 may include a transparent plastic material, may prevent foreign substances from being introduced the light emitting module 130 through the cover member 136, and may ensure durability against corrosion.

In the light emitting device 100 according to an embodiment of the present disclosure, a cable connector 141 for connection of the cable 140 may be formed at an end of the LED array member 133, may be coupled to the cable connector 141, supported through the aforementioned cable holder 170, and connected to the electronic controller 150.

Referring to FIG. 2 together, the light emitting device 100 according to an embodiment of the present disclosure may control at least one of the color, brightness, or cycle of the light 131 emitted from the light emitting module 130 through the electronic controller 150. In particular, the electronic controller 150 may control the light emitting module 130 based on driving information of the vehicle. Here, the driving information of the vehicle may include at least one of information on a driving mode, a driving direction, parking, or an external environment.

For example, the driving information may include various information representing a driving state and behavior of the vehicle, such as a steering angle formed as a vehicle occupant manipulates a steering wheel, an accelerator pedal stroke or brake pedal stroke formed as the vehicle occupant presses an accelerator pedal or a brake pedal, and a vehicle speed, acceleration, yaw, pitch, and roll as a behavior formed in the vehicle. The aforementioned driving information may be obtained through a steering angle sensor, an accel position sensor (APS)/pedal travel sensor (PTS), a vehicle speed sensor, an acceleration sensor, a yaw/pitch/roll sensor, and the like that are located in the vehicle. The driving information of the vehicle may include location information of the vehicle, and the location information of the vehicle may be obtained through a global positioning system (GPS) receiver applied to the vehicle.

The electronic controller 150 may control at least one of the color, brightness, or cycle of the light 131 emitted from the light emitting module 130, and for example, the color, brightness, or cycle of the light 131 emitted according to an eco mode and a sports mode may be changed depending on a driving mode. The color, brightness, or cycle of the light 131 may be changed to indicate a direction in conjunction with a turn signal light. To ensure a side view of the vehicle at night, the brightness of the light 131 emitted from the light emitting module 130 may be controlled to improve the convenience of vehicle parking.

FIG. 7 is a diagram for explaining the wear sensor 134 of the light emitting device 100 according to an embodiment of the present disclosure.

In the light emitting device 100 according to an embodiment of the present disclosure, the light emitting module 130 may include the wear sensor 134 that is coupled to the LED array member 133 and is in contact with one surface of the brake pad 160. A wear state of the brake pad 160 may be checked based on a change in resistance value measured by the wear sensor 134, and the light emitting module 130 may be controlled through the electronic controller 150.

More specifically, when the brake pad 160 is worn, a thickness t of the brake pad 160 becomes thinner, and eventually the wear sensor 134 comes into direct contact with the brake disc 10. In this case, a wire 135 of the wear sensor 134 is broken by the rotating brake disc 10, and a resistance value measured by the wear sensor 134 may be changed due to breakage of the wire 135.

Therefore, the light emitting device 100 according to an embodiment of the present disclosure may check a wear state of the brake pad 160 through a change in the resistance value measured by the wear sensor 134, and may control at least one of the color, brightness, or cycle of the light 131 emitted from the light emitting module 130 through the electronic controller 150 as described above, and thus may provide a visual notification according to wear of the brake pad 160.

In the light emitting device 100 according to an embodiment of the present disclosure, the cable 140 may include the wire 135 connected to the wear sensor 134 as well as the wire connected to the light emitting module 130 and may be connected to the electronic controller 150.

Summarizing the above, the light emitting device and the vehicle including the same according to the present disclosure may include a light emitting module that emits light into a gap of a caliper body, and control the light emitting module through an electronic control unit to beautify the caliper body. Visual notification may be provided by checking the wear state of the brake pad through the wear sensor and controlling the light emitting module. Visual information may be provided by controlling the light emitting module based on the driving information of the vehicle.

The light emitting device and the vehicle including the same according to the present disclosure may include a light emitting module that emits light into a gap of a caliper body, and control the light emitting module through an electronic control unit to beautify the caliper body.

Visual notification may be provided by checking the wear state of the brake pad through the wear sensor and controlling the light emitting module.

Visual information may be provided by controlling the light emitting module based on the driving information of the vehicle.

It will be appreciated by persons skilled in the art that the effects that could be achieved with the present disclosure are not limited to what has been particularly described hereinabove and other advantages of the present disclosure will be more clearly understood from the above detailed description.

The above detailed description is to be construed in all aspects as illustrative and not restrictive. The scope of the present disclosure should be determined by reasonable interpretation of the appended claims and all changes coming within the equivalency range of the present disclosure are intended to be embraced in the scope of the present disclosure.

What is claimed is:

1. A light emitting device provided in a vehicle, the light emitting device comprising:
a caliper body;
an installation bracket located on an accommodation surface inside the caliper body;
a light emitting module installed on the installation bracket and configured to emit light into a gap of the caliper body;
a cable connected to the light emitting module; and
an electronic control unit (ECU) connected to the cable,
wherein the ECU controls at least one of a color, brightness, or cycle of the light emitted from the light emitting module.

2. The light emitting device of claim 1, wherein the light emitting module includes:
a plurality of light emitting diodes (LEDs); and
an LED array member on which the plurality of LEDs are arranged,
wherein the LED array member includes a bendable strap or line form.

3. The light emitting device of claim 2, further comprising a brake pad apart from the installation bracket and located inside the caliper body,
wherein the light emitting module includes a wear sensor that is coupled to the LED array member and is in contact with one surface of the brake pad.

4. The light emitting device of claim 3, wherein the ECU controls the light emitting module based on a change in resistance value measured by the wear sensor.

5. The light emitting device of claim 2, wherein the light emitting module includes a cover member configured to cover the plurality of LEDs and surround the LED array member.

6. The light emitting device of claim 2, wherein the LED array member is attached to the installation bracket through an adhesive or fastened and coupled to the installation bracket through a bolt.

7. The light emitting device of claim 1, further comprising a cable holder coupled to the caliper body and configured to support the cable,
wherein the cable holder includes a hook in contact with the cable.

8. The light emitting device of claim 1, wherein the ECU controls the light emitting module based on driving information of the vehicle.

9. The light emitting device of claim 8, wherein the driving information includes at least one of information on a driving mode, a driving direction, parking, or an external environment.

10. A vehicle comprising:
a vehicle body;
a plurality of wheels located at a lower part of the vehicle body to rotate and including a brake disc; and
a plurality of light emitting devices provide in the plurality of wheels, respectively,
wherein at least one of the plurality of light emitting devices includes:
a caliber body into which one end of the brake disc is inserted;
an installation bracket located on an accommodation surface inside the caliper body;
a light emitting module installed on the installation bracket and configured to emit light into a gap of the caliper body;
a cable connected to the light emitting module; and
an electronic control unit (ECU) connected to the cable,
wherein the ECU controls at least one of a color, brightness, or cycle of the light emitted from the light emitting module.
